(19) United States
(12) Patent Application Publication
(10) Pub. No.: US 2024/0246195 A1
(43) Pub. Date: Jul. 25, 2024

(54) METHOD FOR PRODUCING RESIN MEMBER USED IN PRODUCTION PROCESS OF ELECTRONIC DEVICES

(71) Applicant: FUJIMI INCORPORATED, Aichi (JP)

(72) Inventors: Yasuhiro Moroe, Aichi (JP); Hitoshi Morinaga, Aichi (JP)

(21) Appl. No.: 18/561,562

(22) PCT Filed: Apr. 28, 2022
(86) PCT No.: PCT/JP22/19300

§ 371 Date: Nov. 16, 2023

(30) Foreign Application Priority Data
May 17, 2021 (JP) 2021-83505

(51) Int. Cl. B24B 55/00; B24B 7/22

(52) U.S. Cl. CPC B24B 55/00; B24B 7/22

(57) ABSTRACT

There is provided a method for producing a resin member used in a production process of electronic devices capable of suppressing the adhesion of adhering substances to the surface over a long period of term. The method for producing a resin member used in a production process of electronic devices includes: a processing step of applying abrasive processing to the surface of a raw member to set a surface roughness Ra to 100 nm or less and a contact angle of pure water with respect to the surface to 70° or more and less than 110°.

### TECHNICAL FIELD

The present invention relates to a method for producing a resin member used in a production process of electronic devices.

### BACKGROUND ART

Resin has been used in various applications due to its processability, water repellency, oil repellency, low friction properties, chemical resistance, corrosion resistance, insulation properties, and the like. Particularly, in a production process of electronic devices, wet processes using chemicals or processing liquids, such as cleaning, polishing, and plating, are frequently performed. Therefore, from the viewpoint of chemical resistance or corrosion resistance, resin is particularly preferably used as raw materials for piping members or bathtubs.

When a resin member is used in a production process of electronic devices, dust is generated from the surface of the resin member or adhering substances adhering to the surface of the resin member are detached, posing a risk of contamination of the electronic device. This has posed a risk that the electrical characteristics of the produced electronic device deteriorate, reducing the yield. Examples of the adhering substances adhering to the surface of the resin member includes substances generated by adhesion and accumulation of contaminants derived from the processing liquids above to/on the surface of the resin member. Therefore, it is required to suppress the generation of dust from the surface of the resin member or the detachment of the adhering substance adhering to the surface of the resin member over a long period of time.

Conventionally, used as the resin member are those having a surface roughness Ra (smoothness of the surface) ranging from submicron to several tens of nanometers (see, for example, PTL 1). However, it is difficult to sufficiently suppress the generation of dust from the surface of the resin member or the detachment of the adhering substance adhering to the surface of the resin member over a long period of term only by controlling the surface roughness Ra of the resin member, and thus a further improvement has been required.

### CITATION LIST

### Patent Literature

PTL 1: JP 6-293069 A

### SUMMARY OF INVENTION

### Technical Problem

It is an object of the present invention to provide a method for producing a resin member used in a production process of electronic devices capable of suppressing the adhesion of adhering substances to the surface over a long period of term.

### Solution to Problem

As a result of extensive examinations, the present inventors have found that, by applying abrasive processing to the surface of a resin member to reduce the surface roughness and achieve a specific contact angle, the adhesion of adhering substances to the surface of the resin member can be suppressed over a long period of term, and thus have completed the present invention.

More specifically, a method for producing a resin member used in a production process of electronic devices according to one aspect of the present invention is a method for producing a resin member used in a process of producing electronic devices, and includes: a processing step of applying abrasive processing to the surface of a raw member to set the surface roughness Ra to 100 nm or less and the contact angle of pure water with respect to the surface to 70° or more and less than 1100.

### Advantageous Effects of Invention

The present invention can provide a resin member used in a production process of electronic devices capable of suppressing the adhesion of adhering substances to the surface over a long period of term.

### DESCRIPTION OF EMBODIMENTS

One embodiment of the present invention will now be described in detail. The embodiment described below illustrates one example of the present invention, and the present invention is not limited to this embodiment. The embodiment described below can be variously modified or improved, and such modified or improved aspects may also be included in the present invention.

### <Production Process of Electronic Devices>

A method for producing a resin member used in a production process of electronic devices according to this embodiment is a method for producing a resin member used in a process of producing electronic devices. The type of the electronic devices includes, but is not particularly limited to, semiconductor devices, hard disks, sensors, photomasks, MEMS (Micro Electro Mechanical Systems), and Micro-LED (Light Emitting Diode), for example. Among the above, in processes of producing semiconductor devices and hard disks, the yield is greatly influenced by minute contamination, and therefore the resin member used in a production process of electronic devices according to this embodiment is suitably used for the processes.

The type of the production process of electronic devices includes, but is not particularly limited to, wet processes, such as polishing, cleaning, photolithography, plating, and anodizing, for example. Among the above, polishing, cleaning, and photolithography are processes which are sensitive to contamination and in which the contamination has a significant influence on the yield. Therefore, the resin member used in a production process of electronic devices according to this embodiment is suitably used for these processes.

Further, the resin member used in a production process of electronic devices according to this embodiment is used for a process of producing electronic devices, and particularly suitably usable used in a production process of electronic devices in which the surface of the resin member for production process of electronic devices is kept wet when the resin member used in a production process of electronic devices is used in a production process of electronic devices.

Examples of cases where the surface of the resin member used in a production process of electronic devices is kept wet include, for example, a case where the resin member used in a production process of electronic devices is used in a state of being partially or entirely immersed in a liquid, such as pure water or a solution, and a case where the resin member used in a production process of electronic devices is used in a state of partially or entirely contacting a liquid, such as pure water or a solution. Of these cases, the case where the resin member used in a production process of electronic devices is used in the state of being entirely immersed in a liquid, such as pure water or a solution, and the case where the resin member used in a production process of electronic devices is used in the state of entirely contacting a liquid, such as pure water or a solution, are more preferable.

### <Resin Member>

The type of resin forming the resin member used in a production process of electronic devices according to this embodiment is not particularly limited, and is preferably a resin having high water repellency. Examples of the resin having high water repellency include, for example, fluororesin, polyphenylene sulfide (PPS), polyetheretherketone (PEEK), and the like.

Examples of fluororesin include, for example, fully fluorinated resins, such as polytetrafluoroethylene (PTFE), partially fluorinated resins, such as polychlorotrifluoroethylene (PCTFE), polyvinylidene fluoride (PVDF), and polyvinyl fluoride (PVF), and fluorinated resin copolymers, such as perfluoroalkoxy resin (PFA), tetrafluoroethylene/hexafluoropropylene copolymer (FEP), ethylene/tetrafluoroethylene copolymer (ETFE), and ethylene/chlorotrifluoroethylene copolymer (ECTFE), and the like.

A method for preparing a raw member (resin member before abrasive processing) of the resin member used in a production process of electronic devices (production method) according to this embodiment includes, but is not particularly limited to, machining, such as cutting and grinding, molding, such as injection, film forming, coating, and the like, for example.

### <Processing Step (Abrasive Processing Method)>

An abrasive processing method for the raw member in the method for producing the resin member used in a production process of electronic devices according to this embodiment includes, but is not particularly limited to, processing using fixed abrasives, such as sandpaper, resin bond pellets, metal bond pellets, and electrodeposition grindstone, and polishing (CMP) using free abrasives, for example.

In final finishing of the resin member, polishing using free abrasives is preferably applied. In processing in the stage prior to the final finishing (pre-processing), processing using fixed abrasives may be applied.

The method for producing a resin member used in a production process of electronic devices according to this embodiment is applicable regardless of the surface properties (e.g., surface roughness) of the resin member before the abrasive processing, but is particularly preferably applicable to a resin member having the surface roughness Ra before the abrasive processing of 100 nm or more.

The mechanism by which the abrasive processing improves stain resistance is not always clear, but can be inferred as follows, for example. The following factors are considered as the cause of the generation of the source of contamination of electronic devices from the surface of the resin member: (1) Since the surface of the resin member has high water repellency due to the high contact angle, contaminants originating from a processing liquid cannot be washed away by a dispersion medium when the contaminants adhere to the surface of the resin member in the wet processes in the production of electronic devices, so that the contaminations are more likely to remain on the surface of the resin member, and are detached from the surface of the resin member to become the source of contamination; (2) Since the resin member is soft, the surface of the resin member is likely to be damaged during the execution of molding, cutting, coating, and the like of the resin member, various types of contaminations, which are difficult to remove, adhere to and remain in a part of the damage, and then the contaminations are detached from the surface of the resin member to become the source of contamination during the production process of electronic devices; and (3) The surface roughness of the resin member is large, and projection portions generate dust, becoming the source of contamination.

The stain resistance is considered to improve due to the following factors: (1) Although the high contact angle of the surface of the resin member is considered to be expressed due to a state where the atoms of the surface of the resin after molding are bonded at a high degree, the bonding state on the surface is moderately cut by applying the abrasive processing to the surface of the resin member, obtaining an effect of adjusting the contact angle to a specific contact angle; (2) The abrasive processing has an effect of removing various types of contaminations adhering to the surface of the resin member during the execution of molding, cutting, coating, and the like of the resin member; and (3) The abrasive processing can smooth the surface of the resin member, and thus has an effect of suppressing the generation of dust from the projection portions of the surface of the resin member. The mechanisms above are based on supposition, and the correctness or incorrectness of the mechanisms has no influence on the technical scope of the present invention.

### <Abrasives>

The abrasives used for the abrasive processing have a function of mechanically polishing the resin member (raw member) as an object to be polished. The type of the abrasives includes, but is not particularly limited to, particles containing at least one species of oxides of silicon and oxides of metallic elements, such as alumina, silica, cerium oxide, zirconia, titania, iron oxide, and manganese oxide. Among the above, alumina and silica are suitable, with alumina being the most suitable. Alumina may be any of α-alumina, δ-alumina, θ-alumina, κ-alumina, and amorphous alumina, with α-alumina being the most suitable.

The average secondary particle diameter in terms of volume of the abrasives (hereinafter sometimes also referred to as “D50”) is not particularly limited, and is preferably 0.01 μm or more, more preferably 0.03 μm or more, still more preferably 0.05 μm or more, yet still more preferably 0.1 μm or more, even yet still more preferably 0.3 μm or more, and most preferably 0.5 μm or more. Within this range, a high polishing removal rate can be achieved. The average secondary particle diameter in terms of volume of the abrasives is preferably 3 μm or less, more preferably 2 μm or less, and still more preferably 1.5 μm or less. Within this range, the surface properties of the resin member are improved. In the present embodiment, the average secondary particle diameter in terms of volume is the cumulative median measured by a laser diffraction scattering particle diameter distribution analyzer.

The 10% particle diameter in the cumulative particle diameter distribution in terms of volume (the particle diameter in which the cumulative frequency from the small particle diameter side is 10%, hereinafter sometimes also referred to as “D10”) of the abrasives is not particularly limited, and is preferably 0.005 μm or more, more preferably 0.01 μm or more, still more preferably 0.02 μm or more, yet still more preferably 0.05 μm or more, even yet still more preferably 0.2 μm or more, and most preferably 0.4 μm or more. Within this range, a high polishing removal rate can be achieved. The D10 is preferably 2 μm or less, more preferably 1.5 μm or less, still more preferably 1.0 μm or less, and most preferably 0.8 μm or less. Within this range, the surface properties of the resin member are improved.

The 90% particle diameter in the cumulative particle diameter distribution in terms of volume (the particle diameter in which the cumulative frequency from the small particle diameter side is 90%, hereinafter sometimes also referred to as “D90”) of the abrasives is not particularly limited, and is preferably 0.02 μm or more, more preferably 0.04 μm or more, still more preferably 0.1 μm or more, yet still more preferably 0.3 μm or more, even yet still more preferably 0.6 μm or more, particularly preferably 1.0 μm or more, and most preferably 1.3 μm or more. Within this range, a high polishing removal rate can be achieved. The D90 is preferably 8 μm or less, more preferably 5 μm or less, and still more preferably 3 μm or less. Within this range, the surface properties of the resin member are improved.

The ratio of D90 to D50 (D90/D50) of the abrasives is not particularly limited, and is preferably 1.1 or more, more preferably 1.2 or more, and still more preferably 1.3 or more. Within this range, a high polishing removal rate can be achieved. The D90/D50 is preferably 3.0 or less, more preferably 2.5 or less, and still more preferably 2.2 or less. Within this range, the surface properties of the resin member are improved.

The ratio of D90 to D10 (D90/D10) of the abrasives is not particularly limited, and is preferably 1.2 or more, more preferably 1.5 or more, and still more preferably 2.0 or more. Within this range, a high polishing removal rate can be achieved. The D90/D10 is preferably 7.0 or less, more preferably 6.0 or less, and still more preferably 5.0 or less. Within this range, the surface properties of the resin member are improved.

The ratio of D50 to D10 (D50/D10) of the abrasives is not particularly limited, and is preferably 1.1 or more, more preferably 1.2 or more, and still more preferably 1.3 or more. Within this range, a high polishing removal rate can be achieved. The D50/D10 is preferably 3.0 or less, more preferably 2.5 or less, and still more preferably 2.2 or less. Within this range, the surface properties of the resin member are improved.

The BET specific surface area of the abrasives is not particularly limited, and is preferably 5 m²/g or more, more preferably 10 m²/g or more, and still more preferably 15 m²/g or more. The BET specific surface area of the abrasives is preferably 250 m²/g or less, more preferably 100 m²/g or less, still more preferably 50 m²/g or less, and most preferably 25 m²/g or less. Within this range, a high polishing removal rate can be achieved while maintaining good surface properties. The BET specific surface area can be measured, for example, using Flow Sorb II 2300 manufactured by Micromeritics. As gas adsorbed to the free abrasives in the measurement of the BET specific surface area, nitrogen, argon, krypton, and the like are usable.

The shape of the abrasives includes, but is not particularly limited to, shapes, such as a spherical shape, an oval spherical shape, a cocoon shape, a crushed shape, and an angular shape, for example. Among the above, an oval spherical shape, a cocoon shape, a crushed shape, and an angular shape are preferable from the viewpoint of an improvement of a processing speed.

When alumina is used as the abrasives, the a transformation rate is not particularly limited, and is preferably 30% or more, more preferably 50% or more, still more preferably 70% or more, yet still more preferably 80% or more, and particularly preferably 90% or more or more. Within this range, a high polishing removal rate can be achieved while maintaining good surface properties. The a transformation rate can be determined from the cumulative intensity ratio of the (113) plane diffraction lines by X-ray diffraction measurement, for example.

### <Polishing Using Free Abrasives>

When the raw member as the object to be polished is polished using a processing liquid used for the polishing using free abrasives (hereinafter sometimes also referred to as a “polishing composition”), the polishing can be performed by the following operation, for example.

More specifically, in a state where a platen, a polishing pad, and the like are brought into contact with a surface to be polished of the object to be polished, as required in a state where a pressure is applied to the object to be polished, one of the platen, the polishing pad, and the object to be polished is slid against the other while the polishing composition is being supplied between the platen and the polishing pad, and the surface to be polished of the object to be polished, whereby the surface of the object to be polished can be polished.

A device used for the polishing includes, but is not particularly limited to, a stationary polishing device, a hand polisher, a robot including a rotating body, and the like, for example. A method for supplying the polishing composition is not particularly limited, and may be selected as appropriate, depending on the size or the shape (flat shape, shape with a curved surface, or a three-dimensional shape) of the object to be polished or the polishing device, from methods, such as supplying in the one way, supplying in a circulating method, supplying in a state where the polishing composition remains on a surface in contact with the surface to be polished of the object to be polished of the surfaces of the platen and the polishing pad, supplying by dropping the polishing composition onto the object to be polished, scattering by spraying, and supplying by applying.

The concentration of the abrasives contained in the polishing composition is not particularly limited, and is preferably 0.1% by mass or more, more preferably 1% by mass or more, and still more preferably 3% by mass or more. Within this range, a high polishing removal rate can be achieved. The concentration of the abrasives contained in the polishing composition is preferably 40% by mass or less, more preferably 20% by mass or less, and still more preferably 15% by mass or less. Within this range, the cost of the polishing composition becomes appropriate.

The dispersion medium is contained in the polishing composition. The dispersion medium has a function as a medium dispersing or dissolving components other than the dispersion medium in the polishing composition. When water is used as the dispersion medium, industrial water, tap water, distilled water, or filtered pure water, ultrapure water, or the like is usable. Among the above, distilled water, pure water, and ultrapure water are preferable because they contain fewer impurities.

The pH of the polishing composition is preferably 1.0 or more, more preferably 2.0 or more, and still more preferably 3.0 or more. The pH of the polishing composition is preferably 13.0 or less, more preferably 10.0 or less, still more preferably 7.0 or less, and most preferably 5.0 or less. When the pH of the polishing composition is within this range, the polishing ability of the polishing composition is improved and the smoothness of the surface of the resin member after polishing is improved. The pH of the polishing composition can be adjusted by adding known acid, such as nitric acid or sulfuric acid, or known alkali, such as potassium hydroxide, as appropriate.

The polishing composition may further contain a water-soluble polymer. The inclusion of the water-soluble polymer improves the smoothness of the surface of the resin member.

The polishing composition is preferably any one of a slurry form of aqueous solvents, emulsions as mixtures of aqueous and non-aqueous solvents, and high-viscosity compounds obtained by adding a thickening agent to emulsions.

The polishing composition may be prepared by diluting with water a liquid concentrate for dilution produced at a higher concentration than the concentration at the time of use. By producing the liquid concentrate for dilution at a higher concentration than the concentration at the time of use, the transportation cost or the storage space of the polishing composition can be suppressed.

### <Polishing Pad>

When the polishing pad is used for polishing the surface of the raw member, the polishing pad are not particularly limited in the material and the shape, and optional polishing pads, such as a polyurethane type, a non-woven type, a suede type, a wool buff type, a sponge buff type, a pile type, a belt type, and the like are usable, for example. Among the above, the polishing pads of the polyurethane type and the suede type are preferable. The structure of the polishing pad is also not particularly limited. For example, one having a single-layer structure, one having a multilayer structure of two or more layers having a layer supporting the polishing surface on the side opposite to the polishing surface, and the like are usable.

The hardness of the polishing pad is not particularly limited. When a planar object to be polished is polished, the A hardness measured by a method according to JIS K6253 is preferably 50 or more, more preferably 60 or more, and still more preferably 70 or more. The hardness of the polishing pad is preferably 90 or less and more preferably 85 or less.

With regard to the hardness of the polishing pad, when a three-dimensional object to be polished is polished, the C hardness measured by a method according to Annex 2 of JIS K7312:1996 is preferably 40 or more and more preferably 50 or more. The hardness of the polishing pad is preferably 90 or less and more preferably 80 or less. When the hardness of the polishing pad is within this range, the polishing ability of the polishing composition is improved and the smoothness of the surface of the resin member after polishing is improved.

The thickness of the polishing pad is not particularly limited, and is preferably 0.5 mm or more, more preferably 1 mm or more, and still more preferably 2 mm or more. The thickness of the polishing pad is preferably 50 mm or less, more preferably 30 mm or less, and still more preferably 20 mm or less. When the thickness of the polishing pad is within this range, the polishing ability of the polishing composition is improved and the smoothness of the surface of the resin member after polishing is improved.

### <Other Polishing Conditions>

When a pressure is applied to the object to be polished, the pressure is preferably 0.1 kPa or more, more preferably 1 kPa or more, and still more preferably 2 kPa or more. The pressure applied to the object to be polished is preferably 100 kPa or less, more preferably 50 kPa or less, and still more preferably 15 kPa or less. When the pressure is within this range, the polishing ability of the polishing composition is improved and the smoothness of the surface of the resin member after polishing is improved.

The linear velocity when one of the polishing pad and the object to be polished is slid against the other is preferably 10 m/min or more and more preferably 20 m/min or more. The linear velocity is preferably 1000 m/min or less and more preferably 500 m/min or less. When the linear velocity is within this range, the polishing ability of the polishing composition is improved and the smoothness of the surface of the resin member after polishing is improved.

### <Properties of Resin Member Used in Production Process of Electronic Devices>

The surface roughness Ra of the resin member used in a production process of electronic devices is 100 nm or less, preferably 50 nm or less, more preferably 20 nm or less, still more preferably 15 nm or less, and most preferably 10 nm or less. Within this range, the adhesion of contaminations to the surface of the resin member can be suppressed over a long period of term. The surface roughness of the resin member can be measured using a measuring device Laser Microscope VK-X200 manufactured by Keyence Corporation or the like, for example.

The contact angle of pure water with respect to the surface of the resin member used in a production process of electronic devices is 70° or more, preferably 75° or more, more preferably 80° or more, still more preferably 85° or more, and most preferably 90° or more. The contact angle of pure water with respect to the surface is less than 110°, preferably 108° or less, and more preferably 106° or less. When the resin member used in a production process of electronic devices is formed of fluororesin, the contact angle of pure water with respect to the surface is preferably less than 105°.

Within this range, the hydrophilicity of the surface of the resin member falls within an appropriate range, so that the adhesion of contaminations to the surface of the resin member can be suppressed and the stain resistance can be maintained even when the resin member is exposed to contamination over a long period of time. The contact angle of pure water with respect to the surface can be measured using a mobile contact angle meter PG-X+ manufactured by Matsubo Corporation, for example.

The contact angle of pure water with respect to the surface of the resin member used in a production process of electronic devices decreases by the polishing by the abrasive processing or the like by preferably 3° or more, more preferably 5° or more, and still more preferably 7° or more as compared with the contact angle before the polishing. Within this range, the hydrophilicity of the surface of the resin member falls within an appropriate range and the adhesion of contaminations to the surface of the resin member can be further suppressed.

### EXAMPLES

Hereinafter, the present invention is more specifically described with reference to Examples and Comparative Examples.

### Example 1 and Comparative Examples 1 to 3

Resin member s used in a production process of electronic devices of Example 1 and Comparative Examples 1 to 3 are molded articles of perfluoroalkoxy resin (PFA). In Example 1, the surface of the resin member (raw member) was polished with a polishing composition obtained by dispersing alumina in water to have a concentration of 20% by mass. In Comparative Examples 1 and 3, the surfaces of the resin member s (raw member) were polished with sandpaper. The grain size of the sandpaper is #1000 for Comparative Example 1 and #320 for Comparative Example 3. In Comparative Example 2, the surface of the resin member (raw member) was not polished.

The contact angle of pure water with respect to the surface before the polishing, the contact angle of pure water with respect to the surface after the polishing, and the surface roughness Ra of the surface after the polishing were as shown in Table 1. Comparative Example 2 was not polished, and therefore the contact angle of pure water with respect to the surface after polishing is not shown. The contact angle of pure water was measured at a water drop amount of 1.5 μL using a mobile contact angle meter PG-X+ manufactured by Matsubo Corporation. The surface roughness Ra was measured under a condition of a viewing angle of 284×213 μm using a measuring device Laser Microscope VK-X200 manufactured by Keyence Corporation.

The specific polishing conditions of Example 1 are as follows.
Polishing apparatus: EJ-380IN manufactured by ENGIS JAPAN Corporation
Polishing pad: K-lWNX-202U manufactured by Fujibo Ehime Co., Ltd.
Polishing pressure: 15 kPa
Polishing composition supply rate: 30 mL/min

TABLE 1

| | Resin molded article | | | | | | | | |
|---|---|---|---|---|---|---|---|---|---|
| | | | Contact angle | | Surface | Evaluation 1 | | Evaluation 2 | |
| | Resin | | Before | After | roughness | Contamination | Sliding | Contamination | Sliding |
| | type | Polishing | polishing | polishing | Ra [nm] | amount | angle | amount | angle |
| Ex. 1 | PFA | Abrasive | 105° | 99° | 12 | A | 23° | A | 24° |
| | | processing | | | | | | | |
| Ex. 2 | PTFE | Abrasive | 110° | 101° | 14 | A | 23° | A | 24° |
| | | processing | | | | | | | |
| Ex. 3 | PEEK | Abrasive | 85° | 77° | 7 | A | — | — | — |
| | | processing | | | | | | | |
| Comp. | PFA | Abrasive | 105° | 116° | 412 | B | 30° | B | 56° |
| Ex. 1 | | processing | | | | | | | |
| Comp. | PFA | None | 105° | — | 679 | B | 20° | B | 30° |
| Ex. 2 | | | | | | | | | |
| Comp. | PFA | Abrasive | 105° | 151° | 1883 | B | 3° | B | 36° |
| Ex. 3 | | processing | | | | | | | |
| Comp. | PTFE | Abrasive | 110° | 117° | 442 | B | 37° | B | 46° |
| Ex. 4 | | processing | | | | | | | |
| Comp. | PTFE | None | 110° | — | 988 | B | 25° | B | 41° |
| Ex. 5 | | | | | | | | | |
| Comp. | PTFE | Abrasive | 110° | 151° | 3011 | B | 3° | B | 23° |
| Ex. 6 | | processing | | | | | | | |
| Comp. | PEEK | Abrasive | 85° | 87° | 417 | B | — | — | — |
| Ex. 7 | | processing | | | | | | | |
| Comp. | PEEK | None | 85° | — | 700 | B | — | — | — |
| Ex. 8 | | | | | | | | | |
| Comp. | PEEK | Abrasive | 85° | 84° | 1042 | B | — | — | — |
| Ex. 9 | | processing | | | | | | | |

The resin member s of Example 1 and Comparative Examples 1 to 3 were evaluated as follows.

### (Evaluation 1)

The resin members were immersed in a colloidal silica liquid (concentration of 20% by mass) in which colloidal silica having a primary particle size of 100 nm was dispersed in water for 1 hour, followed by replacing with pure water and drying with dry air. Then, the surfaces of the dried resin member s were observed using a scanning electron microscope SU8000 manufactured by Hitachi High-Tech Corporation at a 3000× magnification to evaluate the surface contamination amounts. The results are shown in Table 1.

In Table 1, “A” is indicated when the number of colloidal silica aggregates observed within a 40 μm×40 μm field of view was less than 10 and “B” when the number was 10 or more.

The sliding angles of the colloidal silica liquid above to the surfaces of the dried resin member s were measured. More specifically, the resin members were tilted at a rate of 0.5°/sec using an automatic tilting table manufactured by Mugegawa Seiko Corporation, and the angle at which a 50 μL droplet of the colloidal silica liquid was slid off was defined as the sliding angle. The results are shown in Table 1.

### (Evaluation 2)

The resin members were sprayed for 30 seconds with a colloidal silica liquid (concentration of 20% by mass) in which colloidal silica having a primary particle size of 100 nm was dispersed in water, allowed to stand and dried for one day, and then further cleaned with running water. This operation was repeated six times, and then the surfaces of the resin member s were photographed using a measuring device Microscope VHX-2000 manufactured by Keyence Corporation at a magnification in which the viewing angle was 32 mm×32 mm, and then the generation state of dried aggregates was observed and evaluated. The results are shown in Table 1.

In Table 1, “A” is indicated when no dried aggregates were observed on the surfaces of the resin member s in the photographed images and “B” is indicated when the dried aggregates were observed.

The sliding angles of the colloidal silica liquid above to the surfaces of the resin member s after the operation above was repeated six times were measured. More specifically, the resin members were tilted at a rate of 0.5°/sec using an automatic tilting table manufactured by Mugegawa Seiko Corporation, and the angle at which a 50 μL droplet of the colloidal silica liquid was slid off was defined as the sliding angle. The results are shown in Table 1.

### Example 2 and Comparative Examples 4 to 6

The test was performed in the same manner as in Example 1 and Comparative Examples 1 to 3, except that the resin type was polytetrafluoroethylene (PTFE). The results are shown in Table 1.

### Example 3 and Comparative Examples 7 to 9

The test was performed in the same manner as in Example 1 and Comparative Examples 1 to 3, except that the resin type was polyetheretherketone (PEEK). However, only the contamination amount of Evaluation 1 was evaluated, and the sliding angle of Evaluation 1 and the contamination amount and the sliding angle of Evaluation 2 were not evaluated. The results are shown in Table 1.

As is understood from the results shown in Table 1, the contamination in Evaluation 1 was less in Examples 1 to 3 in which the resin members were subjected to the abrasive processing to have a surface roughness Ra of 100 nm or less and the contact angle of pure water with respect to the surface of 70° or more and less than 110°, and the stain resistance was high.

In Examples 1, 2, the resin member s after continuously subjected to contamination for six days in Evaluation 2 also had less contamination. Further, in Examples 1, 2, the sliding angle as one of the indices of the stain resistance hardly changed from the sliding angle in Evaluation 1, which showed that the surface properties of the resin member s were able to be maintained over a long period of term.

On the other hand, the resin members of Comparative Examples 1 to 9 were more contaminated. In Comparative Examples 1 to 6, the sliding angle in Evaluation 2 greatly changed from the sliding angle in Evaluation 1, which showed that the surface properties of the resin member s were not able to be maintained over a long period of term.

1. A method for producing a resin member used in a production process of electronic devices comprising:
a processing step of applying abrasive processing to a surface of a raw member to set a surface roughness Ra to 100 nm or less and a contact angle of pure water with respect to a surface to 70° or more and less than 110°.

2. The method for producing a resin member used in a production process of electronic devices according to claim 1, wherein
the raw member is formed of fluororesin, and
the processing step is a step of applying the abrasive processing to the surface of the raw member to set the surface roughness Ra to 100 nm or less and the contact angle of pure water with respect to the surface to 85° or more and less than 105°.

3. The method for producing a resin member used in a production process of electronic devices according to claim 1, wherein the processing step is a step of reducing the contact angle of pure water with respect to the surface by 5° or more than the contact angle before the processing by the abrasive processing.

4. The method for producing a resin member used in a production process of electronic devices according to claim 2, wherein the processing step is a step of reducing the contact angle of pure water with respect to the surface by 5° or more than the contact angle before the processing by the abrasive processing.
